(19) United States
(12) Patent Application Publication
(10) Pub. No.: US 2026/0190935 A1
(43) Pub. Date: Jul. 2, 2026

(54) METHOD OF CONTROLLING SUBSTRATE TRANSFER APPARATUS

(71) Applicant: Absolics Inc., Covington, GA (US)

(72) Inventors: SUKWAN YOO, Covington, GA (US); Chaemook LIM, Covington, GA (US); BYUNGJOO PARK, Covington, GA (US); Hyunsik YOON, Covington, GA (US)

(73) Assignee: Absolics Inc., Covington, GA (US)

(21) Appl. No.: 19/433,073

(22) Filed: Dec. 26, 2025

Related U.S. Application Data
(60) Provisional application No. 63/739,131, filed on Dec. 27, 2024.

(51) Int. Cl. H10P 72/30; H10P 72/00

(52) U.S. Cl. CPC H10P 72/3304; H10P 72/0616

(57) ABSTRACT

In one aspect, a method of controlling a substrate transfer apparatus includes generating sequences that include values of a substrate sequence number, a process to be performed on each surface of a glass substrate, and whether inspection is to be performed, processing the sequences, determining, according to a processing order sequence, whether a current surface of a loaded glass substrate corresponds to a processing surface, operating a flipper to invert the loaded glass substrate when it is determined not to correspond to the processing surface, delivering the glass substrate to equipment connected to the substrate transfer apparatus and performing a process according to the processing order sequence, determining whether a value of inspection in the processing order sequence corresponds to inspection, and when it is determined to correspond to inspection, inspecting the processing surface of the glass substrate and outputting an inspection result.

### CROSS-REFERENCE TO RELATED APPLICATION

This application claims the priorities of U.S. Provisional Patent Application No. 63/739,131, filed Dec. 27, 2024, the entire disclosures of which are incorporated herein by reference for all purposes.

### BACKGROUND

### 1. Field

The present invention relates to a method of controlling a substrate transfer apparatus, and more specifically, to a method of controlling an equipment front end module (EFEM) equipped with a flipper.

### 2. Description of the Related Art

Recently, glass substrates have been attracting attention as a replacement for conventional organic substrates in the semiconductor packaging field. Compared to conventional organic substrates, glass substrates offer higher thermal conductivity and a smooth surface, enabling excellent processability into large rectangular panels to make the glass substrates suitable for implementing ultra-fine linewidth semiconductor packaging, and providing advantages such as reducing substrate thickness and lowering power consumption by eliminating the need for an intermediate substrate.

Equipment for processing glass substrates typically employs a single-sided processing style. When double-sided processing is required, it is controlled to perform A-processing via an equipment front end module (EFEM) equipped with a flipper, invert the substrate, and then perform B-processing. However, glass substrates should be controlled to be subjected to A-processing and then subjected to inspection to check for product damage before B-processing is performed, and therefore a limitation arises in that the flipper of the conventional EFEM control for double-sided processing cannot be used. That is, even when glass substrate processing equipment having a double-sided processing style is provided, smooth substrate transfer cannot be achieved by the conventional EFEM control for double-sided processing.

Therefore, it is necessary to develop a unique EFEM control method that allows selection of a process, an inspection function, and a flipper function for double-sided processing of glass substrates.

### RELATED ART DOCUMENTS

### Patent Documents

Korean Patent Application No. 10-2006-0030315
Korean Patent Application No. 10-2007-0030285

### SUMMARY

In one aspect, a method of controlling a substrate transfer apparatus that can perform double-sided processing of a glass substrate with a multi-purpose recipe and check for damage to the glass substrate is provided.

The object of the present invention is not limited to the object described above, and other objects not described herein can be clearly understood from the following description.

A method of controlling a substrate transfer apparatus according to one aspect of the present invention, which is performed by a substrate transfer apparatus equipped with a flipper to achieve the above-described objectives, includes generating sequences that include values indicating a substrate sequence number, a process to be performed on each surface of a glass substrate, and whether inspection is to be performed, according to the number of substrates to be processed and a process to be performed on each surface side of the glass substrate set by a user, processing the sequences, determining, according to a processing order sequence, whether a current surface of a loaded glass substrate corresponds to a processing surface, operating a flipper to invert the loaded glass substrate when it is determined not to correspond to the processing surface, transferring the glass substrate to equipment connected to the substrate transfer apparatus and performing a process according to the processing order sequence, determining whether a value indicating whether or not to perform inspection in the processing order sequence corresponds to performing inspection, and when it is determined to correspond to performing inspection, inspecting the processing surface of the glass substrate and outputting an inspection result.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is a block diagram of an electronic device for performing a method of controlling a substrate transfer apparatus according to one embodiment of the present invention; and

FIG. 2 is a flowchart of the method of controlling the substrate transfer apparatus according to one embodiment of the present invention.

### DETAILED DESCRIPTION OF EXEMPLARY EMBODIMENTS

The advantages and features of the present invention and methods for achieving them will become apparent from the following embodiments, which are described in detail with reference to the accompanying drawings. However, the present invention is not limited to the embodiments described below and may be implemented in various other forms. The embodiments are merely provided to fully disclose the present invention and to fully convey the scope of the invention to those skilled in the art, and the present invention is defined only by the claims. Meanwhile, the terms used in the present specification are intended to describe the embodiments, not to limit the present invention. In the present specification, the singular shall include the plural unless the context requires otherwise.

The present invention relates to a method of controlling a substrate transfer apparatus equipped with a flipper.

The technical feature of embodiments of the present invention is that automatic production and multi-purpose production become possible beyond fixed recipe setting equipment standards by controlling the substrate transfer apparatus so as to perform a flipper function, an inspection function, and a process selection.

Furthermore, defects may be prevented in advance by inspecting glass substrates for each process, and work efficiency may be improved by determining whether to perform an additional inspection or to continue the operation without an additional inspection according to inspection results.

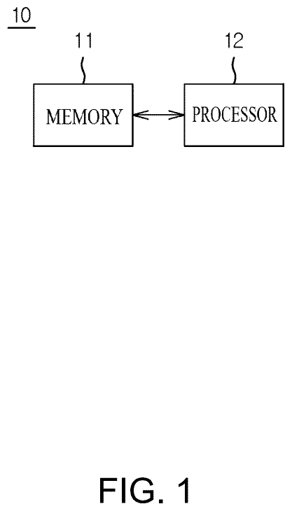

Referring to FIG. 1, an electronic device for performing a method of controlling a substrate transfer apparatus according to one embodiment of the present invention may be configured to include a memory 110 and a processor 120.

The memory 110 may store computer instructions for performing each operation of the method of controlling the substrate transfer apparatus according to one embodiment of the present invention.

The processor 120 may execute the method of controlling the substrate transfer apparatus according to one embodiment of the present invention by performing the computer instructions stored in the memory 110.

In this case, the electronic device 100 may be implemented as a controller of the substrate transfer apparatus equipped with a flipper, and may control the operation of the substrate transfer apparatus equipped with a flipper.

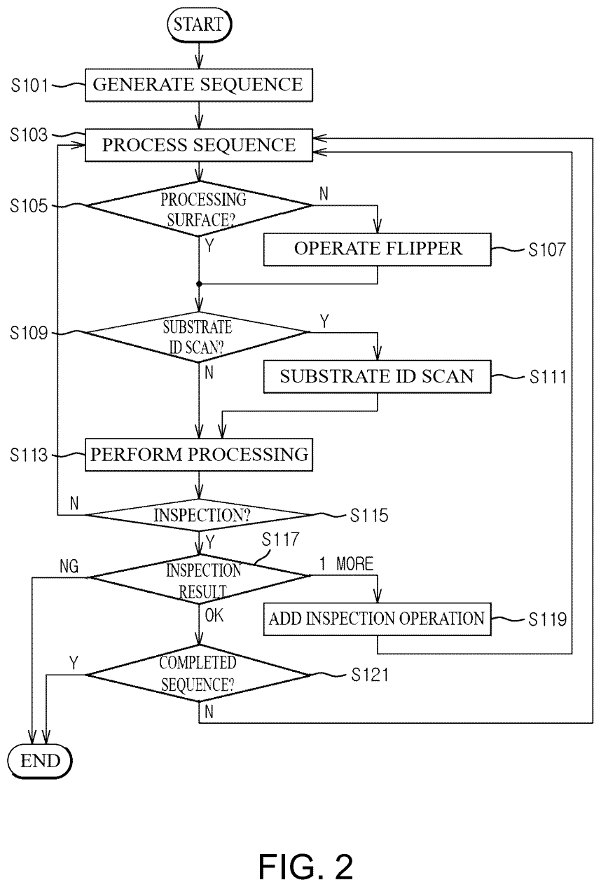

Referring to FIG. 2, the processor 120 may generate sequences that include values indicating a substrate sequence number, a process to be performed on each side of a glass substrate, and whether inspection is to be performed, according to the number of substrates to be processed and a process to be performed on each side of the glass substrate set by a user (S101).

Specifically, the processor 120 may generate, for each substrate sequence number corresponding to the set number of substrates to be processed, a sequence that includes a process to be performed on one side of the glass substrate and a sequence that includes a process to be performed on the other side of the glass substrate, respectively (S101).

In this case, the processor 120 may generate, for a first substrate sequence number among substrate sequence numbers corresponding to the set number of substrates to be processed, a sequence that includes a first value for performing inspection as a value indicating whether or not to perform inspection, and generate, for remaining substrate sequence numbers, a sequence that includes a second value for not performing inspection as a value indicating whether or not to perform inspection.

For example, when double-sided processing is performed, a process to be performed on one side of a glass substrate is recipe A, a process to be performed on the other side of the glass substrate is recipe B, and the number of substrates to be processed is set to 20, the processor 120 may generate sequences that include a glass substrate number, a process, and whether inspection is to be performed, as shown below.
Sequence 1 {panel 1, recipe A, inspection O}
Sequence 2 {panel 1, recipe B, inspection O}
Sequence 3 {panels 2 to 20, recipe A, inspection X}
Sequence 4 {panels 2 to 20, recipe B, inspection X}

Thereafter, the processor 120 may sequentially process the generated sequences. (S103).

The processor 120 may determine, according to a processing order sequence, whether a current surface of a loaded glass substrate corresponds to a processing surface (S105), and, when it is determined that the current surface of the loaded glass substrate does not correspond to the processing surface, may operate a flipper to invert the loaded glass substrate (S107).

Here, the current surface may refer to an upper surface of the loaded glass substrate when a substrate transferred from a loading device or processing equipment is loaded into the substrate transfer apparatus, and the processing surface may refer to one surface of the glass substrate on which processing is performed by processing equipment after the glass substrate is transferred to the processing equipment through the substrate transfer apparatus.

That is, the processor 120 may perform the flipper function so that the current surface of the glass substrate corresponds to the processing surface before performing a process or an inspection.

The processor 120 may determine, after adjusting the current surface of the glass substrate to correspond to the processing surface, whether a substrate ID scan is required (S109), and when it is determined that the substrate ID scan is required, may scan the substrate ID (S111).

The substrate ID scan may be performed when a unique identifier is assigned to each glass substrate and distinguishing the identifier for each glass substrate is required during a process, and since this is not a core aspect of the present invention, a detailed description is omitted.

Subsequently, the processor 120 may deliver the glass substrate to processing equipment connected to the substrate transfer apparatus and may cause the processing equipment to perform a process according to the contents included in the processing order sequence (S113).

The processor 120 may operate the flipper according to whether the current surface of the glass substrate corresponds to the processing surface and may process the glass substrate according to the contents of a sequence being processed, thereby selectively applying recipes to both sides of the glass substrate and enabling multi-purpose production.

The processor 120 may determine whether a value indicating whether or not to perform inspection in the processing order sequence corresponds to performing inspection (S115), and when it is determined to correspond to performing inspection, may inspect the processing surface of the glass substrate and output an inspection result (S117).

In this case, the processor 120 may input the glass substrate into a quality inspection apparatus for quality inspection of the glass substrate and may receive data output as a result of inspection performed by the quality inspection apparatus, and may output OK when data input from the quality inspection apparatus satisfies a preset first criterion, may output 1 MORE when the data does not satisfy the first criterion but satisfies a preset second criterion different from the first criterion, and may output NG when the data does not satisfy the second criterion (S117).

The quality inspection apparatus may inspect the quality of the glass substrate by a transmitted-light method or a reflected-light method, and a conventional quality inspection apparatus may be applied.

The processor 120 may output OK or NG depending on whether the processing order sequence is an odd-numbered sequence or an even-numbered sequence, wherein, when the sequence is an odd-numbered sequence, the processor 120 may inspect the processing surface of the glass substrate through the quality inspection apparatus and may output OK when data output as a result of the inspection satisfies a preset first criterion, and may output NG when the data does not satisfy the first criterion, and, when the sequence is an even-numbered sequence, the processor 120 may inspect the processing surface of the glass substrate through the quality inspection apparatus and may output one of OK, NG, and 1 MORE depending on whether the data output as a result of the inspection satisfies the preset first criterion or a preset second criterion (S117).

The processor 120 may terminate the operation when an output inspection result is NG.

When the output inspection result is OK, the processor 120 may determine whether the generated sequences are completed (S121), and when they are determined not to be completed, the processor 120 may return to the operation S103 for processing each sequence and process the next sequence.

The processor 120 may add an inspection operation when 1 MORE (additional inspection) is output as an inspection result by updating, to a first value for performing inspection, a value indicating whether or not to perform inspection included in a sequence for a substrate sequence number immediately following a substrate sequence number included in the acquired sequence (S119).
Sequence 1 {panel 1, recipe A, inspection O} (Processed)
Sequence 2 {panel 1, recipe B, inspection OK} (Processed)
Sequence 3 {panels 2 to 20, recipe A, inspection X}
Sequence 4 {panels 2 to 20, recipe B, inspection X}

For example, when processing Sequence 1 in the above sequence and an output inspection result is OK, and when processing Sequence 2 and an output inspection result is 1 MORE, the processor 120 may generate a sequence that includes a first value for performing inspection for substrate sequence number panel 2, which is the substrate sequence number immediately following substrate sequence number panel 1 included in the processed sequence, and may update the sequences as shown below.
Sequence 1 {panel 1, recipe A, inspection O} (Processed)
Sequence 2 {panel 1, recipe B, inspection O} (Processed)
Sequence 3 {panel 2, recipe A, inspection O}
Sequence 4 {panel 2, recipe B, inspection O}
Sequence 5 {panel 3 to 20, recipe A, inspection X}
Sequence 6 {panel 3 to 20, recipe B, inspection X}

According to the above configuration, the processor 120 may determine, based on the glass substrate inspection result, whether to continue processing sequences currently involved in an operation, to stop the operation, or to inspect the next glass substrate once more.

According to the embodiments of the present invention, by checking for damage or defects in a glass substrate at each process operation according to a recipe, it is possible to prevent damaged substrates from causing equipment failure and prevent defective products from being produced in the process.

Therefore, advantages such as reducing process costs and improving yield may be expected.

In addition, productivity may be improved by allowing production to continue without an inspection operation for processes confirmed to be defect-free.

According to the embodiments of the present invention, automatic production using a multi-purpose recipe becomes possible, beyond fixed recipe settings by controlling a substrate transfer apparatus.

According to the embodiments of the present invention, an effect is obtained in that damage to a glass substrate can be checked and defects for each process can be identified, thereby preventing equipment failure and defective product generation at an early stage.

The effects of the present invention are not limited to the effects described above, and other effects not described herein can be clearly understood by those skilled in the art from the description of the claims.

Those skilled in the art to which the present invention pertains will understand that the present invention may be embodied in various other specific forms without altering the technical spirit or essential characteristics of the invention. Therefore, the embodiments described above are to be understood as illustrative in all respects and not restrictive. The scope of the present invention is defined by the claims below rather than the detailed description above, and all modifications or variations derived from the claims and their equivalent concepts should be interpreted as being included within the scope of the present invention.

What is claimed is:

1. A method of controlling a substrate transfer apparatus, performed by the substrate transfer apparatus equipped with a flipper, the method comprising:
generating sequences that include values indicating a substrate sequence number, a process to be performed on each side of a glass substrate, and whether inspection is to be performed, according to a set number of substrates to be processed and the process to be performed on each surface side of the glass substrate set by a user;
processing the sequences;
determining, according to a processing order sequence, whether a current surface of a loaded glass substrate corresponds to a processing surface;
operating the flipper to invert the loaded glass substrate when it is determined not to correspond to the processing surface;
transferring the glass substrate to equipment connected to the substrate transfer apparatus and performing a process according to the processing order sequence;
determining whether a value indicating whether or not to perform inspection in the processing order sequence corresponds to performing inspection; and
when it is determined to correspond to performing inspection, inspecting the processing surface of the glass substrate and outputting an inspection result.

2. The method of claim 1, wherein the generating of the sequences includes generating, for each substrate sequence number corresponding to the set number of substrates to be processed, a sequence that includes a process to be performed on one side of the glass substrate and a sequence that includes a process to be performed on the other side of the glass substrate, respectively.

3. The method of claim 2, wherein the generating of the sequences includes generating, for a first substrate sequence number among substrate sequence numbers corresponding to the set number of substrates to be processed, a sequence that includes a first value for performing inspection as a value indicating whether or not to perform inspection, and generating, for remaining substrate sequence numbers, a sequence that includes a second value for not performing inspection as a value indicating whether or not to perform inspection.

4. The method of claim 3, wherein the outputting of the inspection result includes:
outputting, when the processing order sequence includes the process to be performed on one side of the glass substrate, one of OK and NG as the inspection result by inspecting the processing surface of the glass substrate; and
outputting, when the processing order sequence includes the process to be performed on the other side of the glass substrate, one of OK, NG, and 1 MORE as the inspection result by inspecting the processing surface of the glass substrate.

5. The method of claim 4, further comprising, after the outputting of the inspection result, adding an inspection operation when 1 MORE (additional inspection) is output as the inspection result by updating, to the first value for performing inspection, a value indicating whether or not to perform inspection included in a sequence for a substrate sequence number immediately following a substrate sequence number included in the acquired sequence.

6. The method of claim 4, wherein, after the outputting of the inspection result, the operation is terminated when NG is output as the inspection result.

7. The method of claim 4, further comprising, after the outputting of the inspection result, determining, when OK is output as the inspection result, whether the generated sequences are completed,
wherein when the generated sequences are determined not to be completed, returning to the operation of processing each sequence and processing a next sequence.
